(19) United States
(12) Patent Application Publication
(10) Pub. No.: US 2026/0186048 A1
(43) Pub. Date: Jul. 2, 2026

(54) HANDLING APPARATUS AND TESTING SYSTEM

(71) Applicant: ADVANTEST Corporation, Tokyo (JP)

(72) Inventors: Aritomo Kikuchi, Tokyo (JP); Toshiyuki Kiyokawa, Tokyo (JP)

(73) Assignee: ADVANTEST Corporation, Tokyo (JP)

(21) Appl. No.: 19/544,092

(22) Filed: Feb. 19, 2026

Related U.S. Application Data
(63) Continuation-in-part of application No. 18/817,872, filed on Aug. 28, 2024.

(30) Foreign Application Priority Data
Aug. 31, 2023 (JP) 2023-141581

(51) Int. Cl. G01R 31/28

(52) U.S. Cl. CPC G01R 31/2887; G01R 31/2875; G01R 31/2877; G01R 31/2893

(57) ABSTRACT

A handling apparatus handles a panel-shaped object comprising one or more device under tests (DUTs). The handling apparatus includes: a holder that holds the panel-shaped object such that a first surface and a second surface of the panel-shaped object are at least partially exposed from the holder; a first moving device that moves the holder relatively with respect to a probe card disposed in the handling apparatus, wherein the probe card comprises a contactor against which a terminal of the DUTs disposed on the first surface is pressed; one or more temperature adjusting devices that contact the second surface of the panel-shaped object and adjust a temperature of the DUTs; and a second moving device that moves the one or more temperature adjusting devices relatively with respect to the panel-shaped object held by the holder.

### CROSS-REFERENCE TO RELATED APPLICATIONS

The present application claims priority from Japanese Patent Application No. 2023-141581 filed on Aug. 31, 2023, the contents of which are incorporated herein by reference in their entirety.

### BACKGROUND

### Technical Field

The present invention relates to a handling apparatus that handles a panel-shaped object such as a semiconductor wafer for testing a DUT (Device Under Test) included in the panel-shaped object and a testing system that includes the handling apparatus.

### Description of Related Art

As a wafer testing system that tests a semiconductor device formed in a semiconductor wafer, one including a wafer chuck that holds the semiconductor wafer and a temperature adjusting means that adjusts the temperature of the semiconductor wafer is known (refer to, for example, Patent Document 1).

### Patent Document

PATENT DOCUMENT 1: JP 2007-129090 A

In the above-described wafer testing system, the temperature adjusting means is disposed in the wafer chuck that holds the entire surface of the semiconductor wafer. Therefore, the temperature adjusting means adjusts the temperature of the entire semiconductor wafer via the wafer chuck, and it is difficult to quickly adjust the temperature in accordance with the amount of heat generated by the semiconductor device.

### SUMMARY

One or more embodiments of the present invention provide a handling apparatus and a testing system capable of speeding up the temperature adjustment of the DUT.
[1] Aspect 1 of the present invention is a handling apparatus that handles panel-shaped object comprising one or more device under tests (DUTs), the handling apparatus comprising: a holder that holds the panel-shaped object such that a first surface and a second surface of the panel-shaped object are at least partially exposed from the holder; a first moving device that moves the holder relatively with respect t o a probe card disposed in the handling apparatus, wherein the probe card comprises a contactor against which a terminal of the DUTs disposed on the first surface is pressed; one or more temperature adjusting devices that contact the second surface of the panel-shaped object and adjust a temperature of the DUTs; and a second moving device that moves the one or more temperature adjusting devices relatively with respect to the panel-shaped object held by the holder.
[2] Aspect 2 of the present invention may be the handling apparatus of

Aspect 1, wherein the one or more temperature adjusting devices may be configured to contact N number of the DUTs included in the panel-shaped object, and the N number may be a natural number greater than or equal to 1 and less than or equal to 8.
[3] Aspect 3 of the present invention may be the handling apparatus of Aspect 1 or 2, wherein the holder may hold an outer peripheral part of the second surface of the panel-shaped object such that the second surface of the panel-shaped object is at least partially exposed from the holder, and the one or more temperature adjusting devices may contact an exposed part of the second surface from the holder.
[4] Aspect 4 of the present invention may be the handling apparatus of any one of Aspects 1 to 3, wherein the holder may comprise an annular holding part that holds an outer peripheral part of the second surface of the panel-shaped object.
[5] Aspect 5 of the present invention may be the handling apparatus of Aspect 1 or 2, wherein the holder may hold an outer peripheral part of the first surface of the panel-shaped object, and the one or more temperature adjusting devices may contact the second surface of the panel-shaped object.
[6] Aspect 6 of the present invention may be the handling apparatus of any one of Aspects 1, 2 and 5, wherein the holder may comprise an annular holding part that holds an outer peripheral part of the first surface of the panel-shaped object.
[7] Aspect 7 of the present invention may be the handling apparatus of any one of Aspects 1 to 6, wherein each of the one or more temperature adjusting devices may comprise: a contact block that comprises a first contact surface that contacts the second surface of the panel-shaped object; and at least one of: a heating device that heats the DUTs via the contact block; and a cooling device that cools the DUTs via the contact block.
[8] Aspect 8 of the present invention may be the handling apparatus of any one of Aspects 1 to 6, wherein each of the one or more temperature adjusting devices may comprise: a heating device that contacts the second surface of the panel-shaped object and heats the DUTs; and a cooling block that holds the heating device and comprises a flow path through which a coolant passes.
[9] Aspect 9 of the present invention may be the handling apparatus of Aspect 8, wherein the cooling block may comprise a contact part that surrounds an outer periphery of the heating device and contacts the second surface of the panel-shaped object.
[10] Aspect 10 of the present invention may be the handling apparatus of Aspect 9, wherein the heating device may comprise a planar heater, the planar heater may comprise: a first heater surface that contacts the second surface of the panel-shaped object; and a second heater surface opposite to the first heater surface, and the cooling block may comprise a second contact surface contacting the second heater surface.
[11] Aspect 11 of the present invention may be the handling apparatus of Aspect 9 or 10, wherein the flow path may pass through an inside of the contact part.
[12] Aspect 12 of the present invention may be the handling apparatus of any one of Aspects 1 to 11, wherein the temperature adjusting devices may individually correspond to two or more of the DUTs included in the panel-shaped object.
[13] Aspect 13 of the present invention may be the handling apparatus of any one of Aspects 1 to 11, wherein the temperature adjusting devices may individually correspond to semiconductor devices included in one of the DUTs.
[14] Aspect 14 of the present invention may be the handling apparatus of any one of Aspects 1 to 13, wherein the handling apparatus may further comprise: a controller that controls the first and second moving devices, and the controller may control the first and second moving devices to bring the holder and the one or more temperature adjusting devices closer to the probe card in a pressing direction of the DUTs against the probe card and to press the terminal of the DUTs against the contactor of the probe card.
[15] Aspect 15 of the present invention may be the handling apparatus of any one of Aspects 1 to 14, wherein each of the DUTs may comprise an optical connection part, and the handling apparatus may comprise: an optical probe that inputs and outputs an optical signal to and from the optical connection part; and a third moving device that moves the optical probe.
[16] Aspect 16 of the present invention may be the handling apparatus of any one of Aspects 1 to 15, wherein the panel-shaped object may comprise: a board; and semiconductor devices mounted on the board, each of the DUTs may comprise: a unit board that is a part of the board; and one or more of the semiconductor devices mounted on the unit board, and the one or more temperature adjusting devices may contact at least one of the one or more semiconductor devices
[17] Aspect 17 of the present invention may be the handling apparatus of any one of Aspects 1 to 15, wherein the panel-shaped object may comprise: a board; and semiconductor devices mounted on the board, and the one or more temperature adjusting devices may contact at least one of the semiconductor devices.
[18] Aspect 18 of the present invention may be the handling apparatus of any one of Aspects 1 to 17, wherein the panel-shaped object may have a quadrilateral planar shape with a length larger than 300 mm and a width larger than 300 mm.
[19] Aspect 19 of the present invention is a testing system comprising: the handling apparatus of any one of Aspects 1 to 18; a testing device that tests the one or more DUTs; and the probe card, which is electrically connected to the testing device.

According to one or more embodiments of the present invention, the holder holds the panel-shaped object while exposing the first and second surfaces of the panel-shaped object, and the one or more temperature adjusting devices that are independent of the holder contact the second surface of the panel-shaped object and adjusts a temperature of the DUTs. Therefore, it is possible to speed up the temperature adjustment of the DUTs.

### BRIEF DESCRIPTION OF DRAWINGS

FIG. 1 is a diagram showing the overall configuration of the semiconductor wafer testing system and the internal structure of the prober in the first embodiment of the present invention.

FIG. 2 is a cross-sectional view of the thermal head and optical probe unit and a block diagram showing the control system in the first embodiment of the present invention.

FIG. 3A is a plan view of the holder in the first embodiment of the present invention, and FIG. 3B is a cross-sectional view taken along line IIIB-IIIB in FIG. 3A.

FIG. 4 is a plan view of the thermal head and optical probe unit in the first embodiment of the present invention.

FIG. 5A and FIG. 5B are cross-sectional and plan views showing a modified example of the thermal head and the optical probe unit in the first embodiment of the present invention.

FIG. 6 is a cross-sectional view showing the probe card, the thermal head and the optical probe unit in the second embodiment of the present invention.

FIG. 7 is a cross-sectional view of the probe card and thermal head in the third embodiment of the present invention.

FIG. 8A to FIG. 8C are cross-sectional views showing the method of pressing the semiconductor wafer against the probe card by the prober in the first embodiment of the present invention.

FIG. 9 is a diagram showing the overall configuration of the semiconductor wafer testing system and the internal structure of the prober in the fourth embodiment of the present invention.

FIG. 10 is a diagram showing the overall configuration of the testing system and the internal structure of the handler in the fifth embodiment of the present invention.

FIG. 11 is a plan view showing the panel including the DUTs each of which is a test object of the testing system in the fifth embodiment of the invention.

FIG. 12 is a cross-sectional view showing the thermal head and the DUT board assembly in the fifth embodiment of the present invention.

FIG. 13A is a plan view of the holder in the fifth embodiment of the present invention, and FIG. 13B is a cross-sectional view taken along line XIIIB-XIIIB in FIG. 13A.

FIG. 14 is a cross-sectional view showing the thermal head and the DUT board assembly in the sixth embodiment of the present invention.

### DETAILED DESCRIPTION OF EMBODIMENTS

Hereinafter, embodiments of the invention will be described with reference to the drawings.

### First to Fourth Embodiments

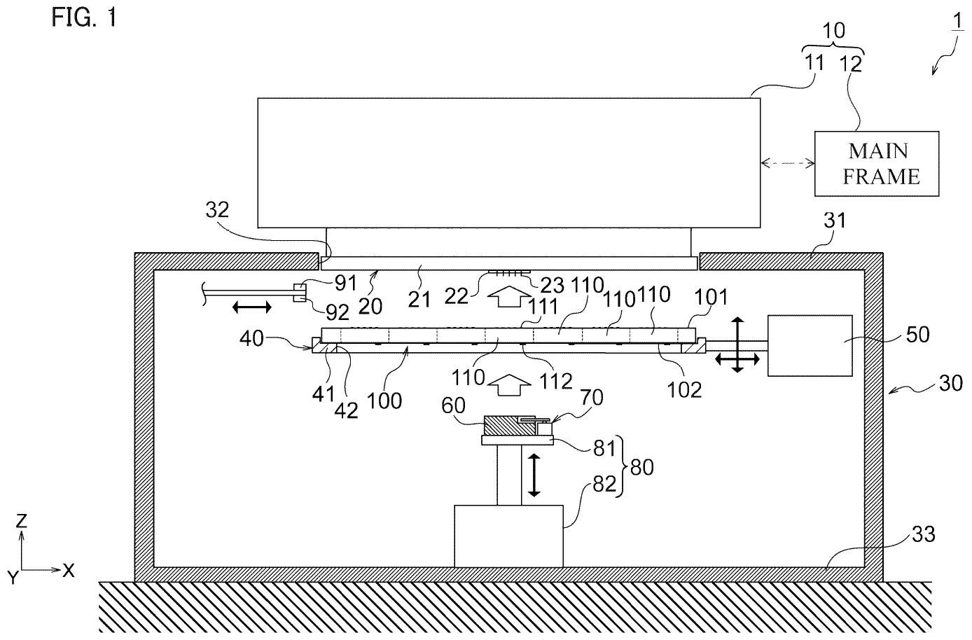

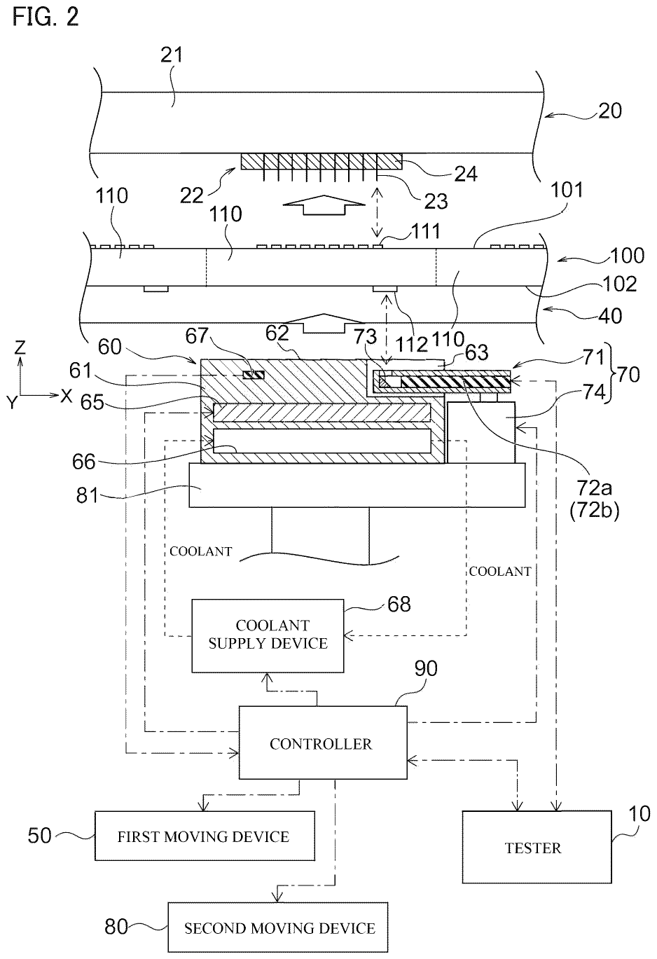

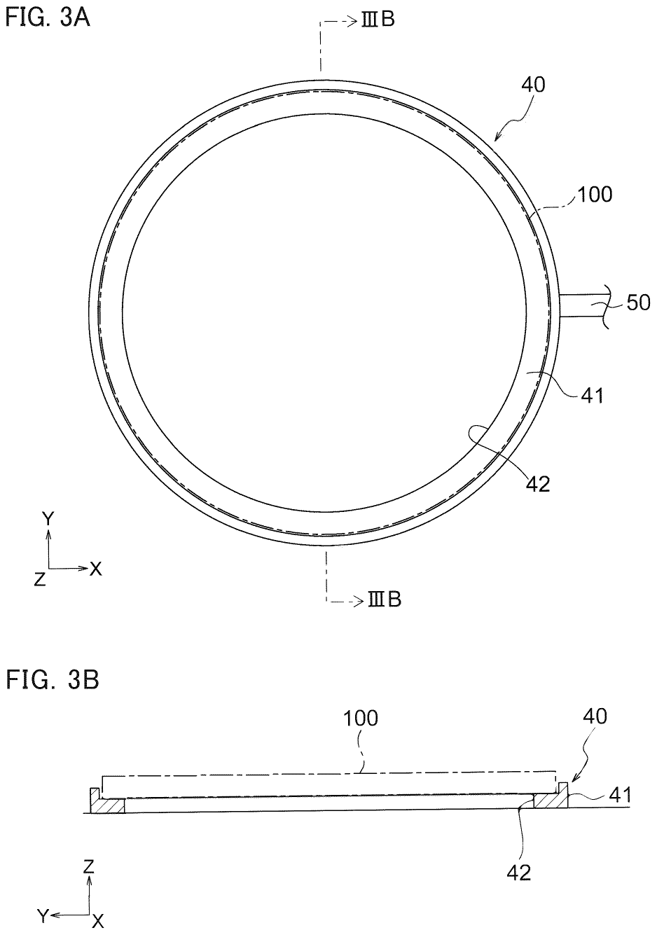

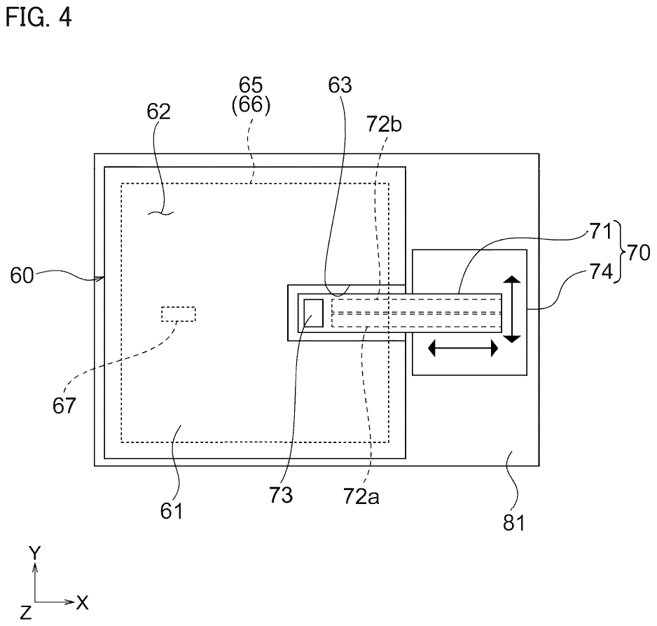

FIG. 1 is a diagram showing the overall configuration of the semiconductor wafer testing system 1 and the internal structure of the prober 30 in the first embodiment of the present invention. FIG. 2 is a cross-sectional view of the thermal head 60 and optical probe unit 70 and a block diagram showing the control system in the first embodiment of the present invention. FIG. 3A and FIG. 3B are plan and cross-sectional views showing the holder 40 in the first embodiment of the present invention. FIG. 4 is a plan view of the thermal head 60 and optical probe unit 70 in the first embodiment of the present invention.

The semiconductor wafer testing system 1 in the first embodiment of the present invention is a system that tests a DUT 110 formed in a semiconductor wafer 100. As shown in FIG. 1, the semiconductor wafer testing system 1 includes a tester 10, a probe card 20, and a prober 30. The semiconductor wafer 100 corresponds to an example of the “panel-shaped object” in the aspect of the present invention, the probe card 20 corresponds to an example of the “contact part” in the aspect of the present invention, the prober 30 corresponds to an example of the “handling apparatus” in the aspect of the present invention, and the semiconductor wafer testing system 1 corresponds to an example of the “testing system” in the aspect of the present invention.

The DUTs 110 are formed in the semiconductor wafer 100. Each of the DUTs 110 that is the test target of the semiconductor wafer testing system 1 is a device capable of handling electrical and optical signals. That is, the DUT 110 is a hybrid circuit device including an electronic circuit and an optical circuit. The optical circuit is formed using, for example, silicon photonics technology. The DUT 110 includes a terminal 111 for inputting and outputting an electrical signal and an optical connection part 112 for inputting and outputting an optical signal. Although not particularly limited, for example, a grating coupler can be exemplified as a specific example of the optical connection part 112. While the terminal 111 is disposed on the upper surface (first surface) 101 of the semiconductor wafer 100, the optical connection part 112 is disposed on the lower surface (second surface) 102 of the semiconductor wafer 100.

During the test of the DUT 110, an electrical signal is input and output to and from the DUT 110 via the terminal 111, and an optical signal is input and output to and from the DUT 110 via the optical connection part 112. When the test is completed, for example, the DUT 110 is individualized by dicing the semiconductor wafer 100, and the individualized DUT 110 is mounted on a board to which an optical fiber and like is connected to form a final product. This final product is, for example, a CPO (Co-Packaged Optics) device.

The tester 10 is a test apparatus that tests the DUT 110 formed in the semiconductor wafer 100 using electrical and optical signals. As shown in FIG. 1, the tester 10 includes a test head 11 and a main frame (tester body) 12. The test head 11 is connected to the main frame 12 via a cable. The probe card 20 is electrically connected to the test head 11. The probe card 20 enters the inside of the prober 30 through an opening 32 formed in an upper base 31 of the prober 30. The probe card 20 is relatively fixed to the prober 30.

The probe card 20 includes a wiring board 21 and a probe head 22 mounted on wiring board 21. The probe head 22 corresponds to one DUT 110 on the semiconductor wafer 100. As shown FIG. 2, the probe head 22 includes a plurality of probes 23 and a housing 24. The probe 23 corresponds to an example of the “contactor” in the aspect of the present invention.

The probe 23 is an electrical probe that contacts the terminal 111 of the DUT 110 of the semiconductor wafer 100. The probes 23 are disposed to respectively correspond to the terminals 111 included in one DUT 110 on the semiconductor wafer 100. Although not particularly limited, for example, a pogo pin, a vertical probe needle, a cantilever-type probe needle, an anisotropic conductive rubber sheet, a bump provided on a membrane, or a contactor manufactured using MEMS technology can be exemplified as a specific example of the probe 23.

The probes 23 are held by the housing 24, and the probe head 22 is mounted to the wiring board 21 by fixing the housing 24 to the wiring board 21 by screws or the like. The wiring board 21 may directly hold the probes 23, and the housing 24 can be omitted in this case.

As shown FIG. 1 and FIG. 2, the prober 30 includes a holder 40, a first moving device 50, a thermal head 60, an optical probe unit 70, a second moving device 80, and a controller 90. The thermal head 60 corresponds to an example of the “temperature adjusting device” in the aspect of the present invention.

In the present embodiment, the semiconductor wafer 100 held by the holder 40 is aligned (positioned) with respect to the probe card 20 by the first moving device 50. Further, the thermal head 60 is brought into contact with the lower surface 102 of the semiconductor wafer 100 by the second moving device 80, and the temperature of the DUT is adjusted by the thermal head 60. Then, the semiconductor wafer 100 is pressed against the probe card 20 by the first and second moving devices 50 and 80 to electrically connect the semiconductor wafer 100 and the probe card 20. In this state, the optical probe 71 is aligned (positioned) with respect to the optical connection part 112 of the DUT 110 by the optical probe unit 70, and then, the tester 10 inputs and outputs electrical signals to and from the DUT 110 via the probe card 20 and inputs and outputs optical signals to and from the DUT 110 via the optical connection part 112 to test the DUT 110.

The holder 40 is a member that holds the semiconductor wafer 100. The holder 40 holds the lower surface 102 of the semiconductor wafer 100, and the entire upper surface 101 of the semiconductor wafer 100 is exposed from the holder 40. As shown in FIG. 3A and FIG. 3B, the holder 40 includes a circular annular holding part 41. The holding part 41 has an opening 42 with an inner diameter smaller than the outer diameter of the semiconductor wafer 100. Therefore, the holding part 41 holds the outer peripheral part of the lower surface 102 of the semiconductor wafer 100. The part of the lower surface 102 of the semiconductor wafer 100 other than the outer peripheral part (the part of the lower surface 102 of the semiconductor wafer 100 that is more inward than the outer peripheral part) is exposed from the holder 40 through the opening 42. The holder 40 may include a holding mechanism that sucks and holds the outer peripheral part of the semiconductor wafer 100. Alternatively, the holder 40 may include a holding mechanism that holds the outer peripheral part of the semiconductor wafer 100 by a mechanical clamp.

The first moving device 50 is a device that may comprises a central processing unit (CPU) or may be controlled by the controller 90, and moves the holder 40. The first moving device 50 is capable of moving the holder 40 in XYZ axis directions in the figure and rotating (θz) the holder 40 around the Z axis. The semiconductor wafer 100 is aligned (positioned) with respect to the probe card 20 by the first moving device 50 such that the terminals 111 of the DUT 110 respectively face the probe 23 of the probe head 22. The first moving device 50 is fixed to, for example, the frame of the prober 30. As long as the installing position of the first moving device 50 is a location where the first moving device 50 is relatively fixed to the frame of the prober 30, the installing position of the first moving device 50 is not limited to the above example. For example, the first moving device 50 may be fixed to the upper base 31 or lower base 32 of the prober 30.

Although not particularly limited, the first moving device 50 includes, for example, an actuator, a transmission mechanism, and a guide mechanism. Although not particularly limited, for example, a motor including an electric motor (rotary motor, linear motor, etc.), and an electric actuator including the electric motor can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

The thermal head 60 is a temperature adjusting device that contacts the lower surface 102 of the semiconductor wafer 100 and adjusts the temperature of the DUT 110. As shown in FIG. 2, the thermal head 60 includes a contact member 61, a heater 65, a flow path 66, and a temperature sensor 67.

The contact member 61 is a block-shaped member having a flat contact surface 62 that contacts the lower surface 102 of the semiconductor wafer 100. The heater 65 is embedded in the contact member 61. The heater 65 is disposed inside the contact member 61 such that the heater 65 corresponds to the entire area of the contact surface 62. Although not particularly limited, a ceramic heater such as an aluminum nitride heater, a silicon nitride heater, and a PTC heater, a polyimide heater, and a cartridge heater can be exemplified as a specific example of the heater 65. The heater 65 is connected to the controller 90. The heater 65 generates heat by the power supplied from the controller 90 and heats the DUT 110 via the contact member 61. The contact surface 62 corresponds to the “first contact surface” in the aspect of the present invention.

The flow path 66 through which a coolant having a temperature lower than room temperature passes is formed inside the contact member 61. The flow path 66 is also disposed inside the contact member 61 such that the flow path 66 corresponds to the entire area of the contact surface 62. A coolant supply device 68 is connected to the flow path 66. As the coolant that is supplied from the coolant supply device 68 passes through the flow path 66, the DUT 110 is cooled via the contact member 61. A liquid or a gas may be used as the coolant flowing through the flow path 66. Although not particularly limited, for example, water and fluorine-based inert liquid can be exemplified as a specific example of a liquid coolant. On the other hand, for example, air and nitrogen can be exemplified as a specific example of gas coolant.

The configuration of the temperature adjusting device that adjusts the temperature of the DUT 110 is not limited to the above example. For example, instead of a heater, a hot medium having a temperature higher than room temperature may be passed through a flow path in the contact member 61. Alternatively, a Peltier element may be used as the heater, or a Peltier element may be used instead of the coolant. The temperature adjusting device may not include either a heating device (e.g., a heater 65B described later) or a cooling device (e.g., a cooling block 61B described later).

The temperature sensor 67 is also embedded in the contact member 61. The temperature sensor 67 is disposed inside the contact member 61 such that the temperature sensor 67 is located near the contact surface 62. The temperature sensor 67 detects the temperature of the DUT 110 via the contact surface 62. The temperature sensor 67 is connected to the controller 90 such that the temperature sensor 67 can output the detection result to the controller 90.

As shown in FIG. 2 and FIG. 4, the optical probe unit 70 includes an optical probe 71 and a third moving device 74. The optical probe 71 is an optical input/output part for inputting and outputting optical signals to and from the optical connection part 112 formed on the lower surface 102 of the semiconductor wafer 100. The optical probe 71 includes optical fibers 72a and 72b and a mirror 73.

Each of the optical fibers 72a and 72b is disposed such that the optical axis thereof is along the XY plane in the figure, and the pair of optical fibers 72a and 72b are disposed in substantially parallel. The optical fibers 72a and 72b are connected to the tester 10 to transmit optical signals. The mirror 73 is disposed on the optical axes of the optical fibers 72a and 72b.

When testing the DUT 110, in a state where the end of the optical probe 71 faces the optical connection part 112 of the semiconductor wafer 100, an optical signal input from the tester 10 is output from one optical fiber 72a toward the mirror 73, and the optical signal is reflected by the mirror 73 and is input to the optical connection part 112 of the semiconductor wafer 100. On the other hand, an optical signal output from the optical connection part 112 of the semiconductor wafer 100 is reflected by the mirror 73 and is input to the tester 10 via the other optical fiber 72b. That is, in the present embodiment, one optical fiber 72a functions as an optical transmission path for input, and the other optical fiber 72b functions as an optical transmission path for output.

In the present embodiment, although the optical probe 71 inputs and outputs optical signals in a non-contact state with the optical connection part 112 of the semiconductor wafer 100, the optical probe 71 and the optical connection part 112 may be in contact with each other. The optical probe 71 may include optical elements other than the optical fibers 72a and 72b and the mirror 73 as an optical transmission path for transmitting optical signals.

The optical probe 71 is supported by a third moving device 74. The third moving device 74 is an alignment device that aligns (positions) the optical probe 71 with respect to the optical connection part 112 of the semiconductor wafer 100. That is, in the present embodiment, the alignment (positioning) of the optical probe 71 with respect to the optical connection part 112 can be performed independently of the alignment (positioning) of the terminal 111 of the DUT 110 with respect to the electric probe 23 of the probe card 20. The third moving device 74 is capable of moving the optical probe 71 in the X and Y axis directions in the figure and rotating (θz) the optical probe 71 around the Z axis. The degree of freedom of the third moving device 74 may be six degrees of freedom including the movement in the Z axis direction and the rotations (θx and θy) around the X and Y axes in addition to the above three degrees of freedom.

Although not particularly limited, the third moving device 74 includes, for example, an actuator, a transmission mechanism, and a guide mechanism. Although not particularly limited, for example, a motor including an electric motor (rotary motor, linear motor, etc.), and an electric actuator including the electric motor and a piezoelectric actuator (actuator using a piezoelectric element) can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

The second moving device 80 is a device that may comprises a central processing unit (CPU) or may be controlled by the controller 90, and moves the thermal head 60 and the optical probe unit 70. As shown in FIG. 1, the second moving device 80 includes a support member 81 and a lifting mechanism 82 that moves the support member 81 in the Z axis direction.

The thermal head 60 and the optical probe unit 70 are supported by a flat support member 81. Specifically, as shown in FIG. 2 and FIG. 4, the contact member 61 of the thermal head 60 and the third moving device 74 of the optical probe unit 70 are fixed to the support member 81. Therefore, the third moving device 74 is capable of relatively moving the optical probe 71 with respect to the thermal head 60.

A groove 63 is formed in the contact member 61 of the thermal head 60. The groove 63 is formed in the contact member 61 such that the groove 63 opens to the contact surface 62 that contacts the semiconductor wafer 100. The optical probe 71 is inserted in the groove 63. A space is secured between the optical probe 71 and the groove 63 such that the optical probe 71 can be moved and rotated by the third moving device 74 described above.

It is possible to increase the contact area of the thermal head 60 with the semiconductor wafer 100 while the optical probe 71 faces the optical connection part 112 of the semiconductor wafer 100 by mutually overlapping the contact member 61 and the optical probe 71. As a result, the temperature of the DUT 110 can be efficiently adjusted by the thermal head 60, and the DUT 110 can be stably pressed against the probe card 20.

As shown in FIG. 1, the lifting mechanism 82 is installed on the lower base 33 of the prober 30 such that the support member 81 faces the probe head 22 of the probe card 20 in the Z axis direction in the figure. When the lifting mechanism 82 raises the support member 81, the thermal head 60 contacts the lower surface 102 of the semiconductor wafer 100, and the end of the optical probe 71 of the optical probe unit 70 faces the optical connection part 112 of the semiconductor wafer 100. The second moving device 80 is a moving device independent of the above-described first moving device 50 and is capable of moving the thermal head 60 and the optical probe unit 70 independently of the holder 40.

Although not particularly limited, the lifting mechanism 82 includes, for example, an actuator, a transmission mechanism, and a guide mechanism. Although not particularly limited, for example, a motor including an electric motor (rotary motor, linear motor, etc.), and an electric actuator including the electric motor can be exemplified as a specific example of the actuator. For example, a ball screw mechanism can be exemplified as a specific example of the transmission mechanism. For example, a linear guide mechanism including a guide rail and a block that can slide on the guide rail can be exemplified as a specific example of the guide mechanism.

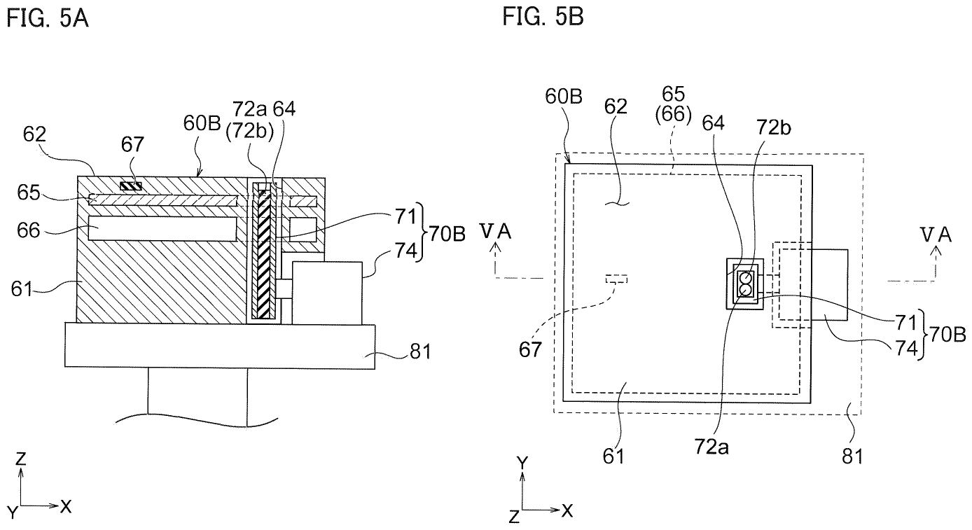

The configuration of the thermal head and the optical probe unit is not limited to the above example. For example, the thermal head and the optical probe unit may be configured as shown in FIG. 5A and FIG. 5B. FIG. 5A and FIG. 5B are cross-sectional and plan views showing a modified example of the thermal head and the optical probe unit in the embodiment of the present invention. FIG. 5A is a cross-sectional view along the line VA-VA in FIG. 5B.

In the thermal head 60B and the optical probe unit 70B shown in FIG. 5A and FIG. 5B, an insertion hole 64 is formed in the contact member 61 along the Z axis direction such that the insertion hole 64 opens to the contact surface 62. The optical probe 71 is inserted in the insertion hole 64. In the modified example, the optical probe 71 does not include a mirror 73 because the optical axes of the optical fibers 72a and 72b are disposed in the Z axis direction in the figure. A space is secured between the optical probe 71 and the insertion hole 64 such that the optical probe 71 can be moved and rotated by the third moving device 74. Thus, it is possible to increase the contact area of the thermal head 60 with the semiconductor wafer 100 while the optical probe 71 faces the optical connection part 112 of the semiconductor wafer 100 by disposing the optical probe 71 in the insertion hole 64 formed in the contact member 61.

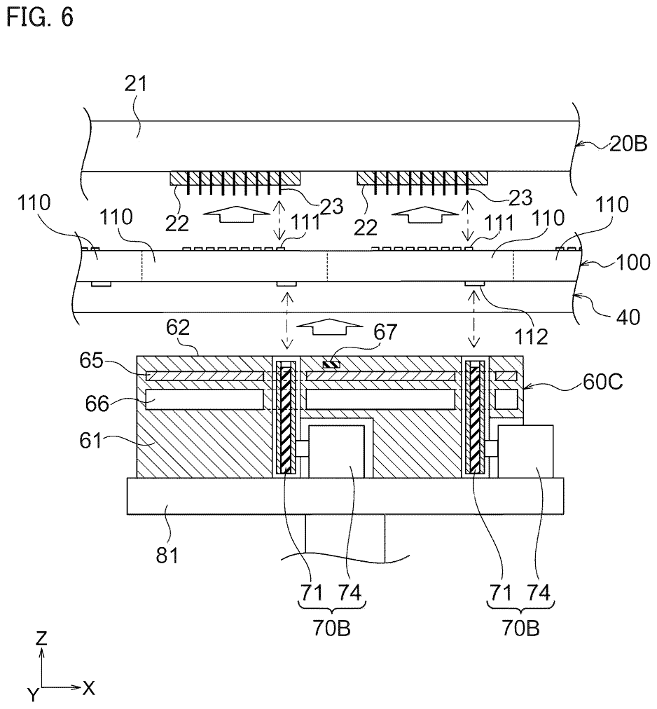

Although only one DUT 110 is tested in one touchdown in the above-described embodiment, a plurality of DUTs 110 may be simultaneously tested in one touchdown. FIG. 6 is a cross-sectional view showing the probe card 20B, the thermal head 60C and the optical probe unit 70B in the second embodiment of the present invention.

For example, as shown in FIG. 6, the case of simultaneously testing two DUTs 110 in one touchdown will be described. In this case, the probe card 20B includes two probe heads 22 disposed on the wiring board 21 to respectively correspond to the two DUTs 110. Furthermore, the contact surface 62 of the thermal head 60C has a size capable of contacting the area corresponding to the two DUTs 110 in the lower surface 102 of the semiconductor wafer 100, and it is possible to adjust the temperature of the two DUTs 110 by one thermal head 60C. On the other hand, two optical probe units 70B are disposed on the support member 81 of the second moving device 80 to respectively correspond to the two DUTs 110. Each of the optical probe units 70B includes an optical probe 71 and a third moving device 74, similar to the above-described optical probe unit 70B. The thermal head 60C and the two optical probe units 70B are disposed on the same support member 81.

Instead of the thermal head 60C, two thermal heads 60B may be disposed on the support member 81 to respectively correspond to the two DUTs 110. In the example shown in FIG. 6, the optical probe unit 70 shown in FIG. 2 and FIG. 4 may be used instead of the optical probe unit 70B.

Although not particularly limited, N number of DUTs 110 that are simultaneously tested in one touchdown is preferably a natural number greater than or equal to 1 and less than or equal to 8 (1≤N≤8). In this case, the probe card includes N number of probe heads 22, and the contact surface 62 of the thermal head has a size capable of contacting the N number of the DUTs 110 among all of the DUTs 110 formed on the semiconductor wafer 100, and the thermal head and N number of optical probe units are disposed on the same support member 81.

Therefore, it is sufficient to locally adjust the temperature of the semiconductor wafer 100 by the thermal head 60, and it is also possible to further speed up the temperature adjustment of the DUT 110. The optical probe unit 70 is required for each DUT 110. Therefore, because the N number is not the number of all of the DUTs 110 included in the semiconductor wafer 100 and is less than or equal to 8, it is possible to limit the increase in the number of optical probe units 70. The N number may be a natural number greater than or equal to 1 and less than or equal to 4 (1≤N≤4), and it may be a natural number greater than or equal to 1 and less than or equal to 2 (1≤N≤2). The number of all of the DUTs 110 included in the semiconductor wafer 100 is greater than the N number.

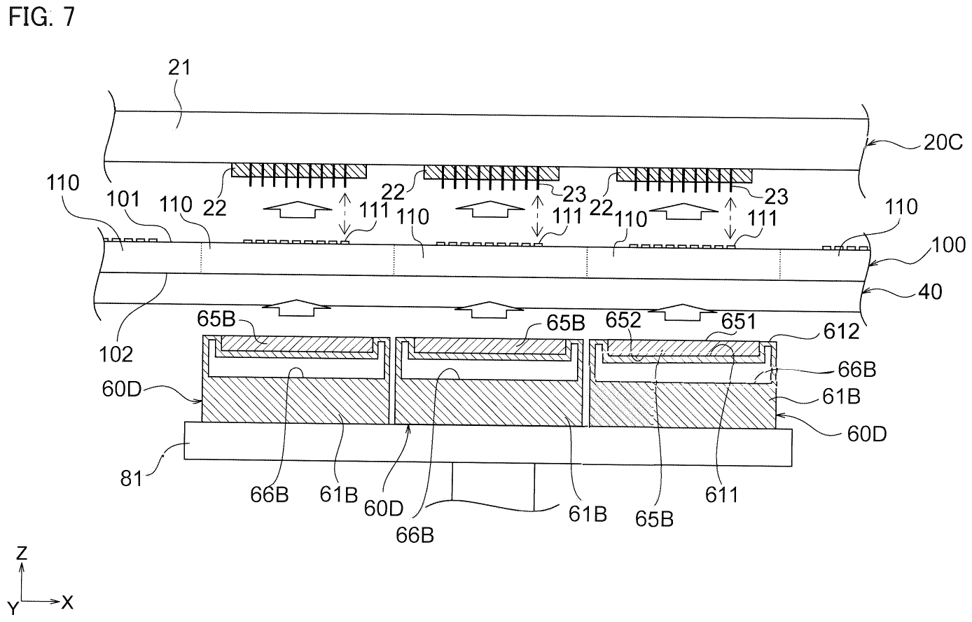

Alternatively, the thermal head may be configured as shown in FIG. 7. FIG. 7 is a cross-sectional view showing the probe card 20C and the thermal head 60D in the third embodiment of the present invention.

In the example shown in FIG. 7, the probe card 20C includes three probe heads 22 disposed on the wiring board 21 to respectively correspond to three DUTs 110. The prober also includes three thermal heads 60D to respectively correspond to the three probe heads 22. The three thermal heads 60D are disposed on the same support member 81.

Each of the thermal heads 60D includes the heater 65B and the cooling block 61B. Although not particularly limited, the heater 65B is a planar heater having an upper surface (first heater surface) 651 that directly contacts the lower surface 102 of the semiconductor wafer 100 and a lower surface (second heater surface) 652 opposite to the upper surface 651. For example, a ceramic heater such as an aluminum nitride heater, a silicon nitride heater, and a PTC heater, a polyimide heater, and a Peltier element can be exemplified as a specific example of the heater 65B.

The cooling block 61B is a block-shaped member that holds the above-described heater 65B. The cooling block 61B has a concave upper part. The heater 65B is housed in the concave part.

Specifically, the cooling block 61B includes a contact surface 611 and an annular protrusion 612 surrounding the outer periphery of the contact surface 611. The contact surface 611 is in contact with the lower surface 652 of the heater 65B. The heater 65B is held by the cooling block 61B in a state where the upper surface 651 of the heater 65B is exposed from the cooling block 61B. When the thermal head 60D contacts the lower surface 102 of the semiconductor wafer 100, the upper surface 651 of the heater 65B directly contacts the lower surface 102 of the semiconductor wafer 100. The protrusion 612 has an annular shape and protrudes upward (in the +Z direction in the figure) from the contact surface 611 to surround the outer periphery of the heater 65B.

The protrusion 612 has a height substantially the same as the thickness of the heater 65B. When the upper surface 651 of the heater 65B directly contacts the lower surface 102 of the semiconductor wafer 100, the protrusion 612 also directly contacts the lower surface 102 of the semiconductor wafer 100. That is, the upper surface 651 of the heater 65B and the upper surface of the protrusion 612 constitute the contact surface 62 of the thermal head 60D that contacts the lower surface 102 of the semiconductor wafer 100. The contact surface 611 corresponds to an example of the “second contact surface” in the aspect of the present invention, and the protrusion 612 corresponds to an example of the “contact part” in the aspect of the present invention.

A flow path 66B through which a coolant having a temperature lower than room temperature passes is formed inside the cooling block 61B. The flow path 66B is formed inside the cooling block 61B to correspond to the entire area of the contact surface 611 and to also pass through the inside of the protrusion 612. Although not specifically shown, similar to the above-described contact member 61, the temperature sensor is embedded in the cooling block 61b.

Although not specifically shown, similar to the above-described heater 65, the heater 65B is connected to the controller 90 and generates heat by the power supplied from the controller 90. Although not specifically shown, similar to the above-described flow path 66, a coolant supply device 68 is connected to the flow path 66B. As the coolant that is supplied from the coolant supply device 68 passes through the flow path 66B, the DUT 110 is cooled.

In the example shown in FIG. 7, the upper surface 651 of heater 65B directly contacts the lower surface 102 of the semiconductor wafer 100, thus the heater 65B directly heats the DUT 110. On the other hand, the cooling block 61B cools the heater 65B contacting the semiconductor wafer 100 and also directly cools the semiconductor wafer 100 with the protrusion 612. Since the annular protrusion 612 of the cooling block 61B surrounds the outer periphery of the heater 65B, it is possible to suppress the thermal expansion of the semiconductor wafer 100 due to the heating of the heater 65B, and it is possible to suppress mis-contact between the probe card 20C and the DUT 110.

For example, when the thermal expansion of the semiconductor wafer 100 due to the heating of the heater 65B is small, only the heater 65B may be exposed from the upper surface of thermal head 60D without including the protrusion 612 in cooling block 61B.

The number of probe heads 22 included in the probe card 20C is not particularly limited to the above example, for example, the probe card 20C may include only one probe head 22. Similarly, the number of thermal heads 60D included in the prober is not particularly limited to the above example as long as it corresponds to the number of probe heads 22. The above-described effect of suppressing thermal expansion is particularly significant when the number of probe heads 22 and the number of thermal heads 60D are multiple. It is preferable that each of the number of probe heads 22 and the number of thermal heads 60D is the above-described N number, therefore it is possible to further speed up the temperature adjustment of the DUT 110.

Although the semiconductor wafer 100 does not include the optical connection part 112 and the prober does not include the optical probe unit 70 in the example shown in FIG. 7, the semiconductor wafer 100 may include the optical connection part 112 and the prober may include the optical probe unit 70 in the example shown in FIG. 7. Alternatively, in the example shown in FIG. 7, instead of the optical probe unit 70, the prober may include the optical probe unit 70B as shown in FIG. 5A and FIG. 5B.

Although the cooling blocks 61B are divided to respectively correspond to the DUTs 110 in the example shown in FIG. 7, a single cooling block 61B may has a size to correspond to the DUT 110s as explained with reference to FIG. 6.

Returning to FIG. 2, the controller 90 includes, for example, a computer. Although not specifically shown, the computer is an electronic computer that includes a CPU (processor), a main memory (such as a RAM), an auxiliary memory device (such as a hard disk or SSD), an interface, and the like. The control described below is functionally realized, for example, by the controller 90 executing a program. The controller 90 may be configured with a circuit board instead of a computer.

As shown in FIG. 2, the controller 90 is electrically connected to the heater 65, the temperature sensor 67, and the coolant supply device 68. The controller 90 controls the heater 65 and the coolant supply device 68 based on the detection result of the temperature sensor 67 to adjust the temperature of the DUT 110 through the contact member 61. The controller 90 may control the heater 65 and the coolant supply device 68 based on the output of the temperature detecting circuit formed in the semiconductor wafer 100 instead of the temperature sensor 67. Although not particularly limited, for example, a circuit including a thermal diode and formed in the semiconductor wafer 100 can be exemplified as a specific example of the temperature detecting circuit.

The controller 90 is connected to the tester 10 such that the controller 90 is capable of transmitting electrical signals to and from the tester 10. The tester 10 has the function to test the electronic circuit of the DUT 110 and the function to test the optical circuit of the DUT 110. The tester 10 is connected to the optical fibers 72a and 72b of the optical probe 71 such that the tester 10 is capable of transmitting optical signals to and from the optical fibers 72a and 72b of the optical probe 71. The function to test the optical circuit of the DUT 110 includes the function of the light source and the function to measure the intensity of light. The controller 90 is connected to the first to third moving devices 50, 80 and 74 such that the controller 90 is capable of outputting control signals to the first to third moving devices 50, 80 and 74. The controller 90 can control the operation of the moving devices 50, 80 and 74. The tester 10 may not have the function to test the optical circuit of the DUT 110. In this case, an external measuring device having the function to test the optical circuit of the DUT 110 is connected to the optical fibers 72a and 72b of the optical probe 71 such that the external measuring device is capable of transmitting optical signals to and from the optical fibers 72a and 72b of the optical probe 71. The external measuring device is a testing device independent of the tester 10 and is, for example, electrically connected to the tester 10.

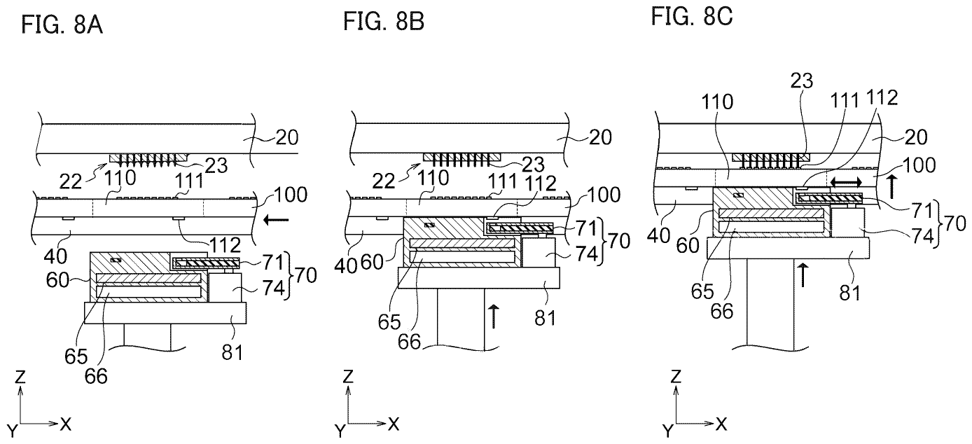

Below, the method of pressing the semiconductor wafer 100 against the probe card 20 by the above-described prober 30 will be explained with reference to FIG. 8A to FIG. 8C. FIG. 8A to FIG. 8C are cross-sectional views showing the method of pressing the semiconductor wafer 100 against the probe card 20 by the prober 30 in the present embodiment.

First, as shown in FIG. 8A, the first moving device 50 moves the holder 40 such that the semiconductor wafer 100 held by the holder 40 faces the probe card 20. At this time, the position of the holder 40 is finely adjusted by the first moving device 50, and the semiconductor wafer 100 is aligned (positioned) with respect to the probe card 20 such that the terminals 111 of the DUT 110 respectively face the probes 23 of the probe head 22.

The relative positional relationship between the terminals 111 of the semiconductor wafer 100 and the probes 23 of the probe card 20 is recognized in advance by, for example, the cameras 91 and 92 (refer to FIG. 1) and the image processing function of the controller 90. Specifically, the cameras 91 and 92 can be moved by a moving device not shown in the figures. The camera 91 captures the image of the probe card 20, and another camera 92 captures the image of the semiconductor wafer 100 held by the holder 40. Then, the relative positional relationship between the terminals 111 and the probes 23 is recognized based on these images by the image processing function of the controller 90. Although not shown in the figures, the semiconductor wafer 100 is supplied to the holder 40 from a cassette such as a FOUP (Front-Opening Unified Pod) by a transfer arm.

Next, as shown in FIG. 8B, the second moving device 80 raises the thermal head 60 and the optical probe unit 70 to bring the thermal head 60 into contact with the semiconductor wafer 100 held by the holder 40. At this time, because the outer peripheral part of the semiconductor wafer 100 is held by the holder 40, the contact surface 62 of the thermal head 60 directly contacts the exposed part of the lower surface 102 of the semiconductor wafer 100 that is more inward than the outer peripheral part. When the thermal head 60 contacts the semiconductor wafer 100, the controller 90 starts controlling the heater 65 and the coolant supply device 68 to adjust the temperature of the DUT 110.

Next, as shown in FIG. 8C, while maintaining the contact state between the thermal head 60 and the semiconductor wafer 100, the first moving device 50 raises the holder 40, the second moving device 80 raises the thermal head 60 and the optical probe unit 70, and the semiconductor wafer 100 is pressed against the probe card 20 to electrically connect the semiconductor wafer 100 and the probe card 20. In this state, the terminals 111 of the DUT 110 are in contact with the probes 23 of the probe card 20.

Next, the third moving device 74 relatively aligns (positions) the end of the optical probe 71 with respect to the optical connection part 112 of the semiconductor wafer 100 by finely adjusting the position of the optical probe 71. Although not particularly limited, the positional relationship between the optical probe 71 and the optical connection part 112 is recognized based on, for example, the intensity of light output from the optical connection part 112.

Specifically, light output from the light source included in the tester 10 is irradiated from the one optical fiber 72a of the optical probe 71 toward the lower surface 102 of the semiconductor wafer 100 including the optical connection part 112. Then, the other optical fiber 72b receives the light output from the optical connection part 112 via a loopback circuit incorporated in the optical circuit of the DUT 110. While this operation is being performed, the third moving device 74 causes the optical probe 71 to scan along the lower surface 102 of the semiconductor wafer 100. Then, the tester 10 measures the intensity of light output from the optical connection part 112, and the controller 90 stops the movement of the optical probe 71 at a position where the intensity of light is equal to or greater than a predetermined value. As a result, the optical probe 71 is aligned (positioned) with respect to the optical connection part 112.

As with the relative positional relationship between the terminal 111 of the semiconductor wafer 100 and the probe 23 of the probe card 20 described above, the relative positional relationship between the optical probe 71 and the optical connection part 112 may be recognized by cameras and an image processing. In this case, for example, the semiconductor wafer 100 held by the holder 40 is imaged from below with a camera and the thermal head 60 is imaged from above with another camera before the thermal head 60 contacts the semiconductor wafer 100 held by the holder 40. Then, the image processing function of the controller 90 recognizes the relative positional relationship between the optical probe 71 and the optical connection part 112 based on these images. Alternatively, the optical probe 71 may be coarsely aligned with respect to the optical connecting part 112 using image processing, and then the optical probe 71 may be precisely aligned based on the intensity of light.

The alignment of the optical probe 71 with respect to the optical connection part 112 may be performed in a state where the thermal head 60 is in contact with the semiconductor wafer 100 held by the holder 40 (the state shown in FIG. 8B). That is, the alignment of the optical probe 71 with respect to the optical connection part 112 may be performed before electrically connecting the semiconductor wafer 100 and the probe card 20.

Next, the tester 10 inputs an electrical signal to the DUT 110 via the electrical probe 23 and the terminal 111, and the tester 10 also inputs an optical signal to the DUT 110 via the optical probe 71 and the optical connection part 112. Then, the tester 10 determines the quality and characteristics of the DUT 110 based on the electrical signal output from the DUT 110 via the terminal 111 and the electrical probe 23 and the optical signal output from the DUT 110 via the optical connection part 112 and optical probe 71.

In the present embodiment, the holder 40 holds the semiconductor wafer 100 while exposing the upper and lower surfaces 101 and 102 of the semiconductor wafer 100, and the thermal head 60 that is independent of the holder 40 contacts the lower surface 102 of the semiconductor wafer 100 and adjusts a temperature of the DUT 110. Therefore, it is possible to speed up the temperature adjustment of the DUT 110.

In particular, in the present embodiment, the thermal head 60 is capable of contacting one to eight DUTs 110 among all of the DUTs 110 formed on the semiconductor wafer 100. Therefore, because the target area for temperature adjustment by the thermal head 60 is small, it is possible to further speed up the temperature adjustment of the DUT 110.

Further, in the present embodiment, the prober 30 includes the third moving device 74 that moves the optical probe 71 independently of the first moving device 50 that aligns the semiconductor wafer 100 with respect to the probe card 20. Therefore, it is possible to relatively align (position) the optical probe 71 with respect to the optical connection part 112 of the DUT 110 in a state where the semiconductor wafer 100 is held by the holder 40. Further, even if the accuracy of the alignment of the optical probe 71 with respect to the optical connection part 112 is higher than that of the electrical probe 23 with respect to the terminal 111, it is possible to align the optical probe 71 with respect to the optical connection part 112 with high accuracy by the third moving device 74.

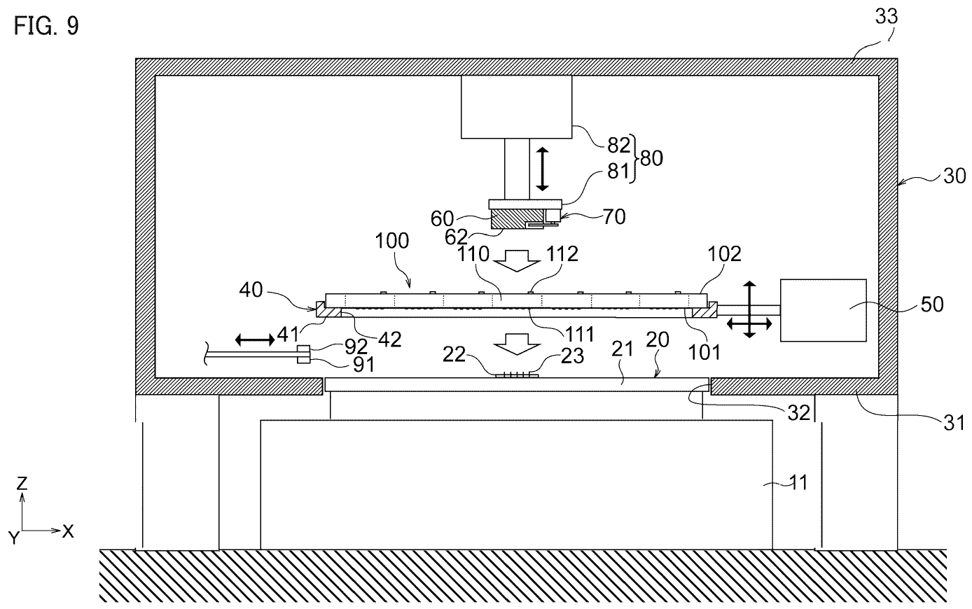

As shown in FIG. 9, the semiconductor wafer testing system 1 may be configured to test the semiconductor wafer 100 in a posture opposite in the vertical direction to that of the above-described embodiments. FIG. 9 is a diagram showing the overall configuration of the semiconductor wafer testing system and the internal structure of the prober in the fourth embodiment of the present invention.

In this case, as shown in FIG. 9, the annular holding part 41 of the holder 40 holds the lower surface (first surface) 101 of the semiconductor wafer 100. The upper surface (second surface) 102 of the semiconductor wafer 100 faces upward, and the entire upper surface 102 is exposed from the holder 40. The probe card 20 is disposed below the holder 40 with the probes 23 facing upward, and the second moving device 80 is disposed above the holder 40 with the contact surface 62 of the thermal head 60 and the optical axis of the optical probe unit 70 facing downward. That is, in the embodiment shown in FIG. 9, all the components except for the holder 40 are inverted from the above-described first embodiment.

### Fifth and Sixth Embodiments

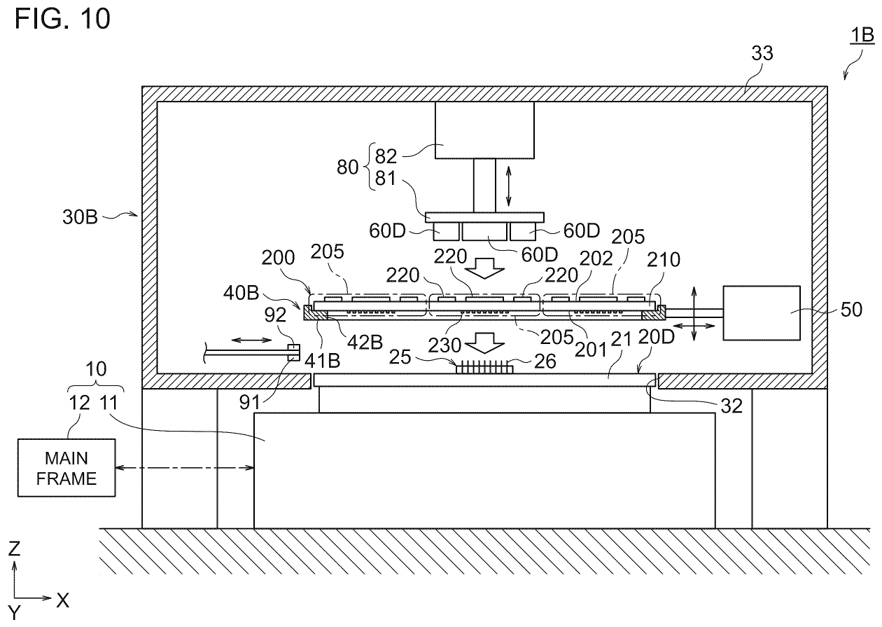

The test system 1B in the fifth embodiment of the present invention will be described with reference to FIG. 10 to FIG. 13B.

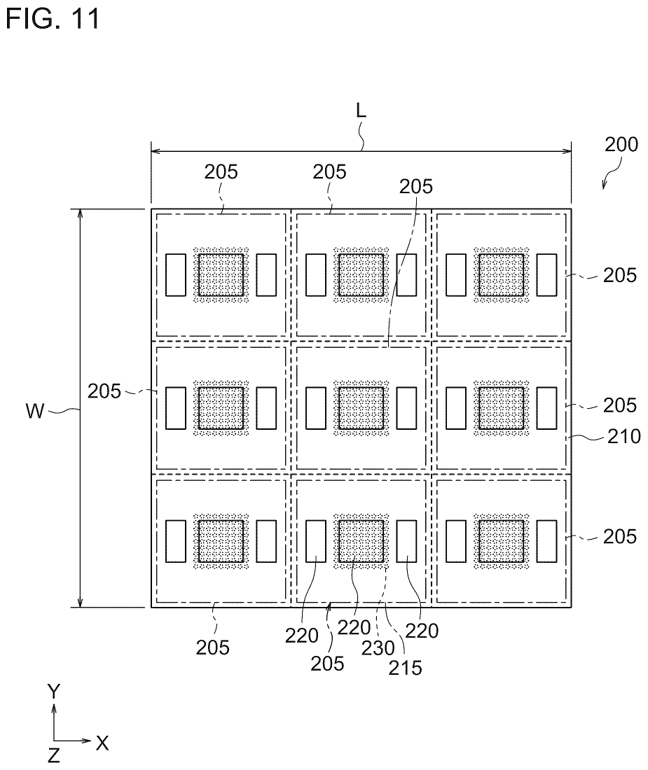

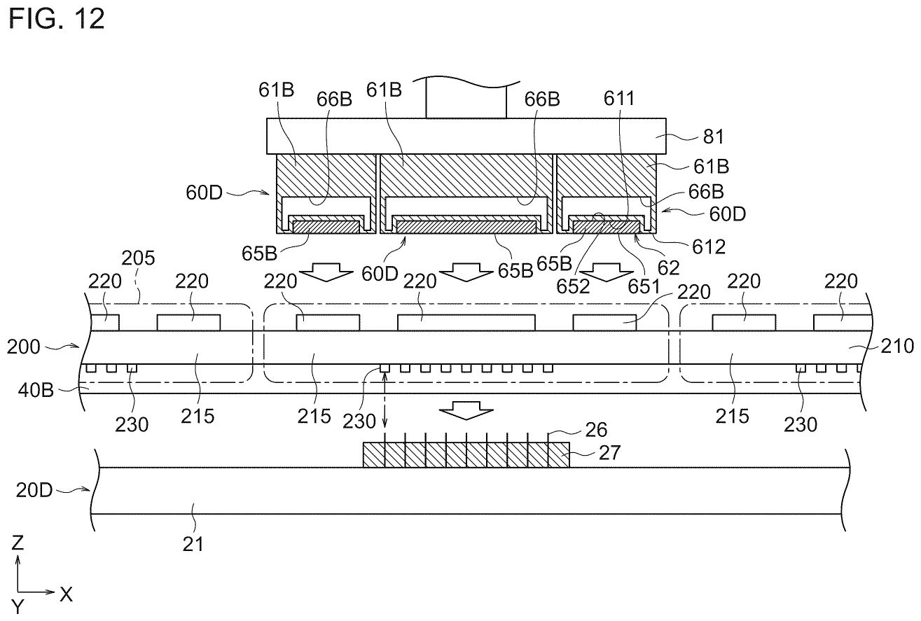

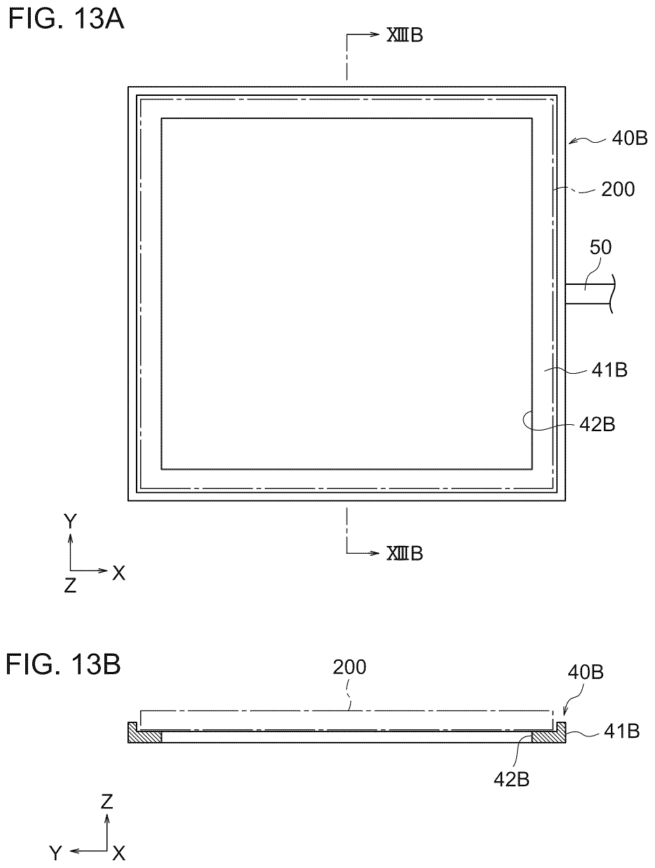

FIG. 10 is a diagram showing the overall configuration of the testing system 1B and the internal structure of the handler 30B in the fifth embodiment of the present invention. FIG. 11 is a plan view showing the panel 200 including the DUTs 205 each of which is a test object of the testing system 1B in the fifth embodiment of the invention. FIG. 12 is a cross-sectional view showing the thermal head 60D and the DUT board assembly 20D in the fifth embodiment of the present invention. FIG. 13A is a plan view of the holder 40B in the fifth embodiment of the present invention, and FIG. 13B is a cross-sectional view taken along line XIIIB-XIIIB in FIG. 13A.

The testing system 1B in the fifth embodiment of the present invention is a system that tests a DUT 110 included in a panel 200. As shown in FIG. 10, the testing system 1B includes a tester 10, a DUT board assembly 20D, and a handler 30B. The panel 200 corresponds to an example of the “panel-shaped object” in the aspect of the present invention, the DUT board assembly 20D corresponds to an example of the “contact part” in the aspect of the present invention, and the handler 30B corresponds to an example of the “handling apparatus” in the aspect of the present invention.

As shown in FIG. 10 and FIG. 11, the panel 200 includes a board 210, semiconductor devices 220, and terminals 230. The panel 200 has a square planar shape. The length L of the panel 200 is greater than 300 mm and equal to or less than 1000 mm (300 mm<L≤1000 mm), and the width W of the panel 200 is greater than 300 mm and equal to or less than 1000 mm (300 mm<W≤1000 mm). The planar shape of the panel 200 is not limited to a square, and may be, for example, a rectangle.

The board 210 is a wiring board that includes a substrate having electrical insulation properties and conductive paths such as wiring patterns formed in the substrate. Although not particularly limited, specific examples of the board 210 include a glass epoxy board, a glass board, and an organic resin board. While the semiconductor devices 220 are mounted on one main surface (the upper surface in FIG. 10) of the board 210, the terminals 230 are formed on another main surface (the lower surface in FIG. 10) of the board 210. Therefore, the semiconductor devices 220 are disposed on the second surface 202 of the panel 200, and the terminals 230 are disposed on the first surface 201 of the panel 200.

The semiconductor device 220 is, for example, a die obtained by individualizing (singulating) a semiconductor wafer. The die includes a semiconductor integrated circuit (electronic circuit) that includes active or passive elements. The semiconductor device 220 may comprise multiple dies stacked on each other, and for example, the multiple dies may be electrically connected to each other through TSV (Through Silicon Via). Alternatively, the semiconductor device 220 may include multiple dies and an interposer on which the multiple dies are mounted.

The panel 200 is divided into a plurality (nine in the present embodiment) of regions, and each of the regions forms a DUT 205. That is, the panel 200 includes a plurality (nine in the present embodiment) of DUTs 205. In the present embodiment, the nine DUTs 205 are arranged in a matrix form in three rows and three columns. In a step subsequent to the test process using the test-system 1B, the DUT 205 are individualized (singulated) by dicing the panels 200. The singulated individual DUT 205 is used, for example, as a semiconductor package.

As shown in FIG. 11, the individual semiconductor device (DUT) 205 includes a unit board 215, a plurality (three in the present embodiment) of semiconductor devices 220, and terminals 230. The unit board 215 is a part of the board 210 obtained by cutting (dicing) the board 210, and functions as a package board of the semiconductor device 220. The unit board 215 may function as an interposer. The semiconductor devices 220 are mounted on the unit board 215. The semiconductor devices 220 and the terminals 230 are electrically connected to each other via conductive path of the unit board 215.

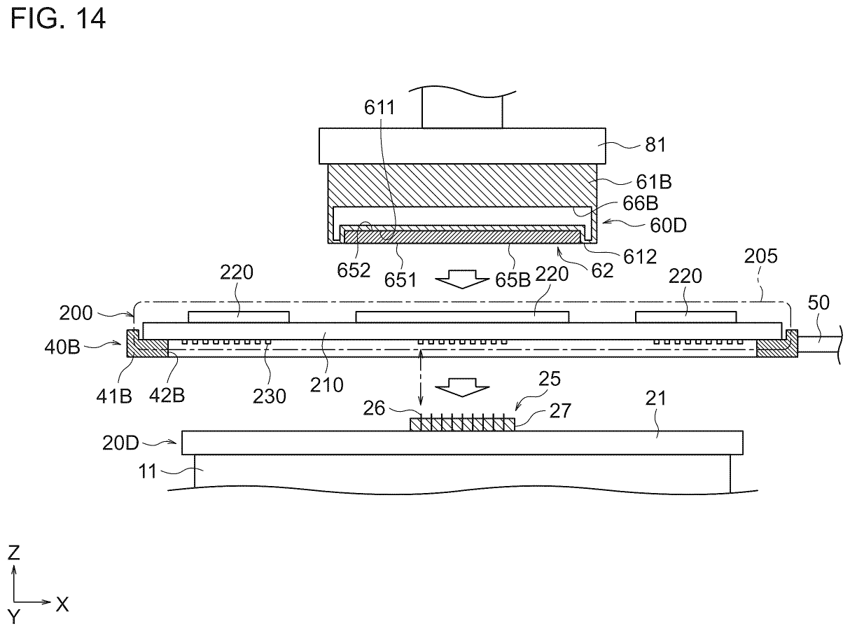

The number and/or arrangement of the DUTs 205 included in the panel 200 are not particularly limited to the above example. Further, the number and/or arrangement of the semiconductor devices 220 included in one DUT 205 are not p articularly limited to the above example, and each DUT 205 may include one or more semiconductor devices 220. In addition, the panel 200 may not be diced after the test process using the test system 1B. That is, the panel 200 may be used as one semiconductor package (see FIG. 14).

The tester 10 is a test apparatus that tests the DUT 205 using an electrical signal. As shown in FIG. 10, the tester 10 includes a test head 11 and a main frame (tester body) 12. The test head 11 is connected to the main frame 12 via a cable. Since the panel 200 described above does not include an optical circuit, the tester 10 does not have a function of testing the optical circuit. The DUT board assembly 20D is electrically connected to the test head 11. The DUT board assembly 20D enters the inside of the handler 30B through an opening 32 formed in an upper base 31 of the handler 30. The DUT board assembly 20D is relatively fixed to the handler 30.

The DUT board assembly 20D includes a DUT board (wiring board 21 and a socket 25 mounted on the DUT board 21. The socket 25 corresponds to one DUT 205 on the panel 200. As shown FIG. 12, the socket 25 includes a plurality of socket pins 26 and a housing 27. The socket pin 26 corresponds to an example of the “contactor” in the aspect of the present invention.

The socket pin 26 contacts the terminal 230 of the DUT 205 of the panel 200. The socket pins 26 are held by the housing 27 such that the socket pins 26 respectively correspond to the terminals 230 included in one DUT 205 included in the panel 200. Although not particularly limited, for example, a pogo pin, a vertical probe needle, a cantilever-type probe needle, an anisotropic conductive rubber sheet, a bump provided on a membrane, or a contactor manufactured using MEMS technology can be exemplified as a specific example of the socket pin 26.

As shown in FIG. 10, the handler 30B includes a holder 40B, a first moving device 50, thermal heads 60D, a second moving device 80, and a controller (not illustrated). Since the panel 200 described above does not include optical circuit, the handler 30B does not include an optical probe unit. The first moving device 50, the second moving device 80, and the controller have the similar configurations to those of the first moving device 50, the second moving device 80, and the controller 90 of the probe 30 described above. The thermal head 60D has the similar configuration to that of the thermal head 60D of the third embodiment described with reference to FIG. 7.

In the present embodiment, similar to the arrangement of the fourth embodiment described with reference to FIG. 9, the holder 40B holds the first surface 201 of the panel 200, the second surface 202 of the panel 200 faces upward, and the entire second surface 202 is exposed from the holder 40B. The DUT board assembly 20D is disposed below the holder 40B with the socket 25 facing upward. The second moving device 80 is disposed above the holder 40B with the contact surface 62 of the thermal head 60D facing downward.

The holder 40B has a different planar shape from that of the holder 40 described above. Specifically, the holder 40B includes a square annular holding part 41B as shown in FIG. 13A and FIG. 13B. The shape of the holding part 41B can be set according to the outer shape of the panel 200 or the like. Although not particularly limited, the holding part 41B may have a rectangular ring shape.

The holding part 41B has an opening 42B that is smaller than the outer shape of the panel 200. Therefore, the holding part 41B holds the outer peripheral part of the lower surface 201 of the panel 200. The part of the lower surface 201 of the panel 200 other than the outer peripheral part, namely, the part of the lower surface 201 of the panel 200 that is more inward than the outer peripheral part is exposed from the holder 40B through the opening 42B. The terminals 230 of the panel 200 are exposed downward through the openings 42B.

Since one DUT 205 includes three semiconductor devices 220 as described above, the handler 30B also includes three thermal head 60D as shown in FIG. 10 and FIG. 12. Similar to the third embodiment described with reference to FIG. 7, the upper surface 651 of the heater 65B and the upper surface of the protrusion 612 constitute the contact surface 62 of the thermal head 60D that contacts the second surface 202 of the panel 200. The three thermal head 60D are fixed to the support member 81 of the second moving device 80 such that the three thermal head 60D respectively correspond to the three semiconductor devices 220 included in one DUT 205. The three thermal head 60D can individually adjust the temperatures of the three semiconductor devices 220.

Although not particularly shown, the number of thermal heads 60D included in the handler 30B may be one. In this case, the cooling-block 61B of the one thermal head 60D has a size corresponding to three semiconductor devices 220, and the one thermal head 60D contacts the three semiconductor devices 220 to adjust the temperature of the three semiconductor devices 220.

Alternatively, for example, among the three semiconductor devices 220, one semiconductor device 220 at the center may be a device that generates a large amount of heat, while the two semiconductor devices 220 at both ends may be devices that generate a small amount of heat. In this case, the number of thermal heads 60D included in the handler 30B may be one, the temperature of the semiconductor device 220 at the center may be adjusted by the one thermal head 60D, and the temperature of the semiconductor device 220 at both ends may not be adjusted.

Although only one DUT 205 is tested in one touchdown in the present embodiment, a plurality of DUTs 205 may be simultaneously tested in one touchdown. Although not particularly limited, N number of DUTs 205 that are simultaneously tested in one touchdown is preferably a natural number greater than or equal to 1 and less than or equal to 8 (1≤N≤8). In this case, the DUT board assembly 20D includes N number of sockets 25 and the handler 30B includes P number of thermal heads 60D. Here, D is the number of the semiconductor devices 220 included in one DUT 205, D=3 in the examples shown in FIG. 10 and FIG. 12, and P is a value obtained by multiplying N by D (P=N×D).

The N number may be a natural number greater than or equal to 1 and less than or equal to 4 (1≤N≤4), and it may be a natural number greater than or equal to 1 and less than or equal to 2 (1≤N≤2). The number of all of the DUTs 205 included in the panel 200 is greater than the N number.

In the present embodiment, the holder 40B holds the panel 200 while exposing the first and second surfaces 201 and 202 of the panel 200, and the thermal head 60D that is independent of the holder 40D contacts the second surface 202 of the panel 200 and adjusts a temperature of the DUT 205. Therefore, it is possible to speed up the temperature adjustment of the DUT 205.

In particular, in the present embodiment, the thermal head 60D is capable of contacting one to eight DUTs 205 among all of the DUTs 205 formed on the panel 200. Therefore, because the target area for temperature adjustment by the thermal head 60D is small, it is possible to further speed up the temperature adjustment of the DUT 205.

As shown in FIG. 14, the entire panel 200 including the three semiconductor devices 220 may be a single DUT 205, and the DUT 205 may be tested while the temperature of the central semiconductor device 220 is controlled by a single thermal head 60D included in the handler 30B. FIG. 14 is a cross-sectional view showing the thermal head 60D and the DUT board assembly 20D in the sixth embodiment of the present invention.

In the embodiment illustrated in FIG. 14, the handler 30B may include a plurality of thermal head 60D. In this case, the Q number of the thermal heads 60D included in the handler 30B is smaller than the X number of all of the semiconductor devices 220 included in the panel 200. The Q number of the thermal head 60D is preferably 1 or more and 8 or less (1≤Q≤8). The Q number may be 1 or more and 4 or less (1≤Q≤4), and may be 1 or more and 2 or less (1≤Q≤2).

It should be noted that the above embodiments are described to facilitate understanding of the invention and are not described to limit the invention. It is therefore intended that the elements disclosed in the above embodiments include all design modifications and equivalents to fall within the technical scope of the present invention.

Although the DUT 110 of the semiconductor wafer 100 is a hybrid circuit element including an optical circuit and an electronic circuit in the first, second, and fourth embodiments described with reference to FIG. 1 to FIG. 6 and FIG. 8A to FIG. 9, the DUT that is a test target may be an electronic circuit element including no optical circuit. In this case, the prober does not include the optical probe units 70 and 70B.

In the fifth and sixth embodiments described with reference to FIG. 10 to FIG. 14, each of the DUTs 205 of the panel 200 may include an optical connection part, and the handler 30B may include an optical probe unit. In this case, the optical connection parts are disposed on the second surface 202 of the panel 200.

In the fifth and sixth embodiments described with reference to FIG. 10 to FIG. 14, the testing system 1B may be configured to test the DUT 205 while holding the panel 200 in a position opposite to that of the fifth and sixth embodiments described above in the vertical direction.

In the fifth and sixth embodiments described with reference to FIG. 10 to FIG. 14, the thermal head 60 described in the first embodiment may be used instead of the thermal head 60D. In this case, as described with reference with FIG. 6, one cooling-block 61B may have a size corresponding to the DUTs 205.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### EXPLANATIONS OF LETTERS OR NUMERALS

1 . . . Semiconductor wafer testing system
1B . . . Testing system
10 . . . Tester
11 . . . Test head
12 . . . Main frame
20, 20B, 20C . . . Probe card
20D . . . DUT board assembly
21 . . . DUT board
22 . . . Probe head
23 . . . Probe
24 . . . Housing
25 . . . Socket
26 . . . Socket pin
27 . . . Housing
30 . . . Prober
30B . . . Handler
31 . . . Upper base
32 . . . Opening
33 . . . Lower base
40, 40B . . . Holder
41, 41B . . . Holding part
42, 42B . . . Opening
50 . . . First Moving device
60, 60B to 60D . . . Thermal head
61 . . . Contact member
61B . . . Cooling block
611 . . . Contact surface
612 . . . Protrusion
62 . . . Contact surface
63 . . . Groove
64 . . . Insertion hole
65, 65B . . . Heater
651 . . . Upper surface
652 . . . Lower surface
66, 66B . . . Flow path
67 . . . Temperature sensor
68 . . . Coolant supply device
70 and 70B . . . Optical probe unit
71 . . . Optical probe
72a, 72b . . . Optical fiber
73 . . . Mirror
74 . . . Third moving device
80 . . . Second moving device
81 . . . Support member
82 . . . Lifting mechanism
90 . . . Controller
91 and 92 . . . Camera
100 . . . Semiconductor wafer
101 . . . Upper surface
102 . . . Lower surface
110 . . . DUT
111 . . . Terminal
112 . . . Optical connection part
200 . . . Panel
201 . . . First surface
202 . . . Second surface
205 . . . DUT
210 . . . Board
215 . . . Unit board
220 . . . Semiconductor device
230 . . . Terminal

What is claimed is:

1. A handling apparatus that handles a panel-shaped object comprising one or more device under tests (DUTs), the handling apparatus comprising:
a holder that holds the panel-shaped object such that a first surface and a second surface of the panel-shaped object are at least partially exposed from the holder;
a first moving device that moves the holder relatively with respect to a probe card disposed in the handling apparatus, wherein the probe card comprises a contactor against which a terminal of the DUTs disposed on the first surface is pressed;
one or more temperature adjusting devices that contact the second surface of the panel-shaped object and adjust a temperature of the DUTs; and
a second moving device that moves the one or more temperature adjusting devices relatively with respect to the panel-shaped object held by the holder.

2. The handling apparatus according to claim 1, wherein
the one or more temperature adjusting devices are configured to contact N number of the DUTs included in the panel-shaped object, and
the N number is a natural number greater than or equal to 1 and less than or equal to 8.

3. The handling apparatus according to claim 1, wherein
the holder holds an outer peripheral part of the second surface of the panel-shaped object such that the second surface of the panel-shaped object is at least partially exposed from the holder, and
the one or more temperature adjusting devices contact an exposed part of the second surface from the holder.

4. The handling apparatus according to claim 1, wherein
the holder comprises an annular holding part that holds an outer peripheral part of the second surface of the panel-shaped object.

5. The handling apparatus according to claim 1, wherein
the holder holds an outer peripheral part of the first surface of the panel-shaped object, and
the one or more temperature adjusting devices contact the second surface of the panel-shaped object.

6. The handling apparatus according to claim 1, wherein
the holder comprises an annular holding part that holds an outer peripheral part of the first surface of the panel-shaped object.

7. The handling apparatus according to claim 1, wherein
each of the one or more temperature adjusting devices comprises:
a contact block that comprises a first contact surface that contacts the second surface of the panel-shaped object; and
at least one of:
a heating device that heats the DUTs via the contact block; and
a cooling device that cools the DUTs via the contact block.

8. The handling apparatus according to claim 1, wherein
each of the one or more temperature adjusting devices comprises:
a heating device that contacts the second surface of the panel-shaped object and heats the DUTs; and
a cooling block that holds the heating device and comprises a flow path through which a coolant passes.

9. The handling apparatus according to claim 8, wherein
the cooling block comprises a contact part that surrounds an outer periphery of the heating device and contacts the second surface of the panel-shaped object.

10. The handling apparatus according to claim 9, wherein
the heating device comprises a planar heater,
the planar heater comprises:
a first heater surface that contacts the second surface of the panel-shaped object; and
a second heater surface opposite to the first heater surface, and
the cooling block comprises a second contact surface contacting the second heater surface.

11. The handling apparatus according to claim 9, wherein
the flow path passes through an inside of the contact part.

12. The handling apparatus according to claim 1, wherein
the temperature adjusting devices individually correspond to two or more of the DUTs included in the panel-shaped object.

13. The handling apparatus according to claim 1, wherein
the temperature adjusting devices individually correspond to semiconductor devices included in one of the DUTs.

14. The handling apparatus according to claim 1, comprising:
a controller that controls the first and second moving devices to bring the holder and the one or more temperature adjusting devices closer to the probe card in a pressing direction of the DUTs against the probe card, and to press the terminal of the DUTs against the contactor of the probe card.

15. The handling apparatus according to claim 1, wherein:
each of the DUTs comprises an optical connection part, and
the handling apparatus further comprises:
an optical probe that inputs and outputs an optical signal to and from the optical connection part; and
a third moving device that moves the optical probe.

16. The handling apparatus according to claim 1, wherein:
the panel-shaped object comprises:
a board; and
semiconductor devices mounted on the board,
each of the DUTs comprises:
a unit board that is a part of the board; and
one or more of the semiconductor devices mounted on the unit board, and
the one or more temperature adjusting devices contact at least one of the one or more semiconductor devices.

17. The handling apparatus according to claim 1, wherein:
the panel-shaped object comprises:
a board; and
semiconductor devices mounted on the board, and
the one or more temperature adjusting devices contact at least one of the semiconductor devices.

18. The handling apparatus according to claim 1, wherein:
the panel-shaped object has a quadrilateral planar shape with a length larger than 300 mm and a width larger than 300 mm.

19. A testing system comprising:
the handling apparatus according to claim 1;
a testing device that tests the one or more DUTs; and
the probe card, which is electrically connected to the testing device.
